(19) United States
(12) Patent Application Publication
(10) Pub. No.: US 2025/0019829 A1
(43) Pub. Date: Jan. 16, 2025

(54) SEMICONDUCTOR WAFER CARRIER STRUCTURE AND METAL-ORGANIC CHEMICAL VAPOR DEPOSITION DEVICE

(71) Applicant: PlayNitride Display Co., Ltd., Zhunan Township (TW)

(72) Inventors: Yen-Lin LAI, Zhunan Township (TW); Jyun-De WU, Zhunan Township (TW); Chi-Heng CHEN, Zhunan Township (TW)

(73) Assignee: PlayNitride Display Co., Ltd., Zhunan Township (TW)

(21) Appl. No.: 18/897,886

(22) Filed: Sep. 26, 2024

Related U.S. Application Data
(63) Continuation of application No. 17/377,079, filed on Jul. 15, 2021.

(30) Foreign Application Priority Data
Apr. 28, 2021 (TW) 110115276

(51) Int. Cl. C23C 16/458; C23C 16/54; H01L 21/02; H01L 21/673; H01L 21/687

(52) U.S. Cl. CPC C23C 16/4584; C23C 16/54; H01L 21/68785; H01L 21/02271; H01L 21/673; H01L 21/68757

(57) ABSTRACT

A semiconductor wafer carrier structure includes a carrier body having a surface, a protective film covering the surface, and a susceptor disposed on the carrier body and having an upper surface. The upper surface is a planar surface. The semiconductor wafer carrier structure further includes a patterned coating film formed on the upper surface and configured to directly face a semiconductor wafer. A material of the patterned coating film is different from the susceptor. The patterned coating film has two or more different thicknesses and is with a pattern, so that the semiconductor wafer is at least locally separated from the patterned coating film due to the pattern. The patterned coating film is continuously and entirely distributed on the upper surface of the susceptor toward the semiconductor wafer, and the upper surface of the susceptor is separated from the semiconductor wafer by the patterned coating film.

### CROSS REFERENCE TO RELATED APPLICATIONS

This application is a continuation application of U.S. application Ser. No. 17/377,079, filed on Jul. 15, 2021, entitled “SEMICONDUCTOR WAFER CARRIER STRUCTURE AND METAL-ORGANIC CHEMICAL VAPOR DEPOSITION DEVICE”, which is hereby incorporated herein by reference.

### BACKGROUND

### Technical Field

The present disclosure relates to semiconductor manufacturing device, and in particular it relates to a semiconductor wafer carrier structure that includes a patterned coating film.

### Description of the Related Art

In recent years, light-emitting diodes (LEDs) have been used in a variety of applications, such as lighting devices, displays, and mobile devices. An LED has the advantages of fast response time, high brightness, small volume, low power consumption, and high color saturation. In order to meet the performance and specifications for various application requirements, LED components of different types or materials are used and always with high demanding for the design and production capabilities of related industries. For example, for the epitaxial layers of micro LEDs applied for display, the high uniformity of the physical and chemical properties thereof is necessary in order to make the wavelength of the display device uniform, and so as to meet the desired display quality.

In the process of manufacturing the epitaxial layer of a micro LED device, the metal-organic chemical vapor deposition (MOCVD) process is a commonly used technique. In order to achieve the required wavelength uniformity in the epitaxial layer, the temperature field distribution of the carrier structure of the device is also a major issue that has to be taken into consideration. If the temperature field distribution of the carrier structure is not uniform, it will lead to nonuniform distribution of the wavelength for the resulting micro LED devices, and may cause the lower yield of component and higher production cost.

Although the existing process can change the temperature field distribution by adjusting the surface depth of the susceptor in the carrier structure through mechanical processing, it is hard to fine-tune the slight temperature changes since the mechanical processing is subject to some inherent limitations, and therefore it is still room for improvement.

### BRIEF SUMMARY

In accordance with some embodiments of the present disclosure, a semiconductor wafer carrier structure is provided. The semiconductor wafer carrier structure includes a carrier body having a surface, a protective film covering the surface, and a susceptor disposed on the carrier body and having an upper surface. The upper surface is a planar surface. The semiconductor wafer carrier structure further includes a patterned coating film formed on the upper surface and configured to directly face a semiconductor wafer. A material of the patterned coating film is different from the susceptor. The patterned coating film has two or more different thicknesses and is with a pattern, so that the semiconductor wafer is at least locally separated from the patterned coating film due to the pattern. The patterned coating film is continuously and entirely distributed on the upper surface of the susceptor toward the semiconductor wafer, and the upper surface of the susceptor is separated from the semiconductor wafer by the patterned coating film.

In accordance with some embodiments of the present disclosure, a metal-organic chemical vapor deposition device is provided. The metal-organic chemical vapor deposition device includes a chamber, the semiconductor wafer carrier structure as described above placed in the chamber, a support member for supporting the semiconductor wafer carrier structure, and a heater disposed below the semiconductor wafer carrier structure for heating the semiconductor wafer carrier structure.

In accordance with some embodiments of the present disclosure, a semiconductor wafer carrier structure is provided. The semiconductor wafer carrier structure includes a carrier body having a surface, a protective film covering the surface, and a susceptor disposed on the carrier body and having an upper surface. The upper surface is a planar surface and is divided into a peripheral surface and a partial surface, the susceptor is provided with a plurality of supporting parts protruding from the peripheral surface and individually distributed around a perimeter of the susceptor, and the supporting parts are configured to support a semiconductor wafer. The semiconductor wafer carrier structure further includes a passivation layer formed on the peripheral surface of the susceptor and the supporting parts and exposing the partial surface of the susceptor, and a patterned coating film formed on the partial surface of the susceptor and configured to directly face the semiconductor wafer. A material of the patterned coating film is different from a material of the susceptor, the patterned coating film has two or more different thicknesses to form a pattern between the supporting parts, and a top of the supporting parts is higher than a top of the patterned coating film in a thickness direction of the susceptor, so that the semiconductor wafer is entirely separated from the pattern of the patterned coating film. The passivation layer and the patterned coating film are continuously and entirely distributed on the upper surface of the susceptor toward the semiconductor wafer, and the upper surface of the susceptor is separated from the semiconductor wafer by the passivation layer and the patterned coating film.

The present disclosure as mentioned provides solutions to keep the temperature field distribution of the carrier structure uniform, and to make the subsequently manufactured LED chips have a consistent light-emitting wavelength.

### BRIEF DESCRIPTION OF THE DRAWINGS

The disclosure can be more fully understood from the following detailed description when read with the accompanying figures. It is worth noting that, in accordance with standard practice in the industry, various features are not drawn to scale. In fact, the dimensions of the various features may be arbitrarily increased or reduced for clarity of discussion.

FIG. 1 illustrates a schematic view of a carrier structure of a semiconductor manufacturing device according to the embodiments of the present disclosure.

FIG. 2 illustrates a cross-sectional view of the carrier structure along line A-A in FIG. 1 according to the embodiments of the present disclosure.

FIG. 3A illustrates a top view of a susceptor with a patterned coating film according to the embodiments of the present disclosure.

FIG. 3B illustrates a cross-sectional view of the susceptor along line 3B-3B in FIG. 3A according to the embodiments of the present disclosure.

FIGS. 4A, 4B, and 4C illustrate a cross-sectional view of the susceptor along line 3B-3B in FIG. 3A according to the embodiments of the present disclosure.

FIG. 5A illustrates a top view of a susceptor with a patterned coating film according to the embodiments of the present disclosure.

FIG. 5B illustrates a cross-sectional view of the susceptor along line 5B-5B in FIG. 5A according to the embodiments of the present disclosure.

FIG. 6A illustrates a light-emitting wavelength distribution profile of a micro LED manufactured by using a susceptor without a patterned coating film according to the embodiments of the present disclosure.

FIG. 6B illustrates a light-emitting wavelength distribution profile of a micro LED manufactured by using a susceptor with a patterned coating film according to the embodiments of the present disclosure.

FIG. 7A illustrates a cross-sectional view of the susceptor with stacked patterned coating films using two or more different materials according to the embodiments of the present disclosure.

FIG. 7B illustrates a cross-sectional view of stacked patterned coating films according to alternative embodiments of FIG. 7A.

FIGS. 8A and 8B illustrate a top view of a susceptor with three different thicknesses of a patterned coating film according to the embodiments of the present disclosure.

FIG. 8C illustrates a cross-sectional view of the susceptor along line 8C-8C in FIGS. 8A and 8B according to the embodiments of the present disclosure.

FIG. 9A illustrates a top view of a susceptor with a plurality of different thicknesses of a patterned coating film according to the embodiments of the present disclosure.

FIG. 9B illustrates a cross-sectional view of the susceptor along line 9B-9B in

FIG. 9A according to the embodiments of the present disclosure.

FIG. 10A illustrates a top view of a susceptor with a plurality of different thicknesses and intermittent patterns of a patterned coating film according to the embodiments of the present disclosure.

FIG. 10B illustrates a cross-sectional view of the susceptor along line 10B-10B in FIG. 10A according to the embodiments of the present disclosure.

FIG. 11A illustrates a top view of a susceptor with a patterned coating film only having a depressed portion according to the embodiments of the present disclosure.

FIG. 11B illustrates a cross-sectional view of the susceptor along line 11B-11B in FIG. 11A according to the embodiments of the present disclosure.

FIG. 12 illustrates a cross-sectional view of a MOCVD device according to the embodiments of the present disclosure.

FIG. 13 illustrates a cross-sectional view of the susceptor with a passivation layer according to the embodiments of the present disclosure.

FIG. 14 illustrates a cross-sectional view of a MOCVD device according to the embodiments of the present disclosure.

### DETAILED DESCRIPTION

The following disclosure provides many different embodiments, or examples, for implementing different features of the subject matter provided. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “about” as used herein indicates the value of a given quantity that can vary based on a particular technology node associated with the subject semiconductor device. In some embodiments, based on the particular technology node, the term “about” can indicate a value of a given quantity that varies within, for example, 10-30% of the value (e.g., ±10%, ±20%, or ±30% of the value).

Unless otherwise defined, all terms (including technical and scientific terms) used in this article have the same meanings as understood by the person having ordinary skill in the art to which the content of the present disclosure belongs. Terms, such as those defined in commonly used dictionaries, should be interpreted as having meanings consistent with the meanings in related fields, and should not be interpreted in an idealized or overly formal sense, unless explicitly defined here.

Compared to the conventional techniques for adjusting the surface depth of a susceptor by using the mechanical processing, in the present disclosure, a patterned coating film is formed on the susceptor to achieve more precise adjustments of the temperature difference on the surface of the susceptor during the process, or to adjust the temperature field distribution on the surface of the susceptor or generate various modes of temperature field distribution according to the desired target wavelength of the wafer (e.g., the wavelength corresponding to light-emitting diodes (LED) chips). For example, in the process of forming the micro LED chips by using metal-organic chemical vapor deposition (MOCVD), a patterned coating film may be formed on the susceptor to produce a uniform temperature field distribution on the surface of the susceptor of the semiconductor wafer carrier structure, which would not be achieved by conventional techniques, thereby enabling the resulting LED chips to have an uniform wavelength distribution. In other embodiments, the temperature field distribution on the surface of the susceptor may also be adjusted such that the micro LED chips have a specific light-emitting wavelength distribution.

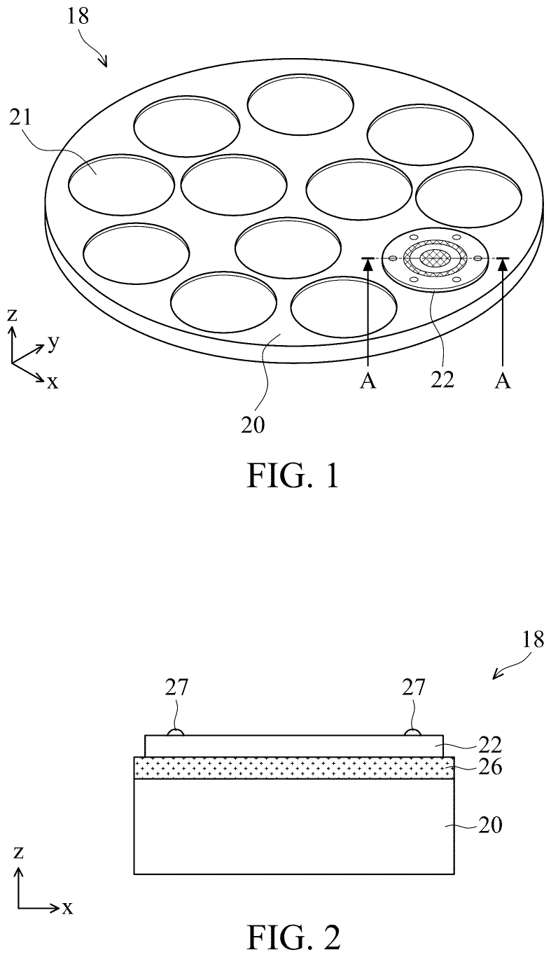

FIG. 1 illustrates a schematic view of a carrier structure 18 according to the embodiments of the present disclosure. Referring to FIG. 1, the carrier structure 18 includes a carrier body 20 and at least one susceptor 22, and the carrier body 20 has at least one circular recess 21 to place the susceptor 22. It is to be understood that although several circular recesses 21 and the susceptor 22 are illustrated in FIG. 1, the carrier body 20 may have only one circular recess 21 and one susceptor 22. The material of the susceptor 22 may include silicon carbide (SiC), graphite, or a combination thereof. In a specific embodiment, the material of the susceptor 22 is silicon carbide.

The carrier structure 18 may carry wafers for the deposition in the MOCVD process, however, the application of the present disclosure is not limited thereto. The carrier structure 18 may also be used in other processes, such as physical vapor deposition (PVD), chemical vapor deposition (CVD), atomic layer deposition (ALD), etc.

FIG. 2 illustrates a cross-sectional view of the carrier structure 18 along line A-A in FIG. 1, which includes a carrier body 20 and a susceptor 22. Typically, the surface of the carrier body 20 is coated with a protective film 26 to protect the carrier body 20 from reacting with the process gas. The susceptor 22 has a plurality of supporting parts 27, which are located at the edge of the susceptor 22. The supporting parts 27 are used to support the wafer so that there is no direct contact between the wafer and the susceptor 22, and the wafer is heated by thermal radiation. For the sake of clarity, the patterned coating film is omitted from the susceptor 22.

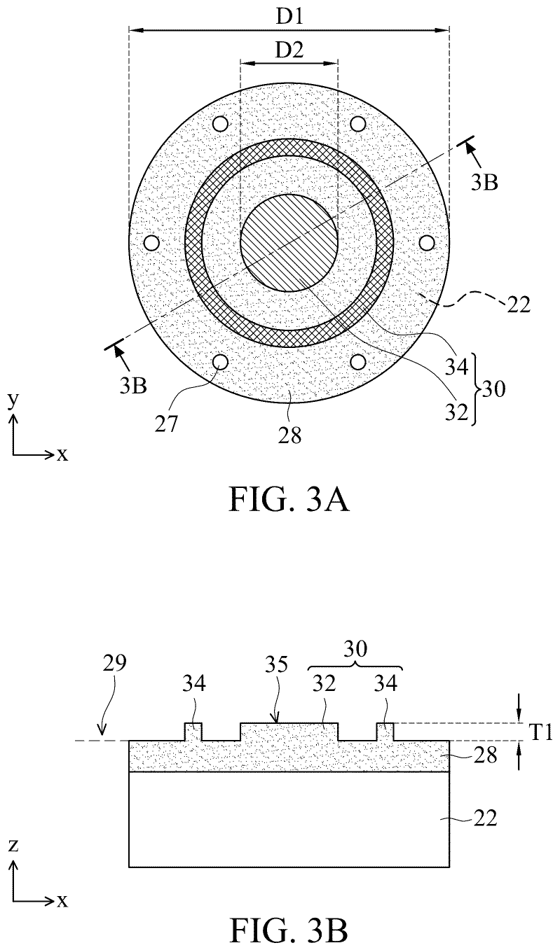

FIG. 3A illustrates a top view of a susceptor 22 with a patterned coating film 28 according to some embodiments of the present disclosure. In some embodiments, a patterned mask (not shown) is used to coat the surface of the susceptor 22 to form a patterned coating film 28 on the susceptor 22. In other embodiments, the coating film may be blanketly formed, and a patterned mask (not shown) may be used to etch the coating film on the surface of the susceptor 22 to pattern the coating film. By using the patterned mask and coating (or etching) technique, the local thickness difference of the susceptor 22 may be finely adjusted. Forming a coating film may increase the thickness of the areas which need to be heated up locally and precisely. The increase in the thickness will increase the thermal mass (heating source) in the areas, which will result in an increase of the temperature in the areas during the process. Similarly, for the areas that need to maintain the original temperature, a patterned mask may be used to cover the areas during the coating process to ensure the thickness of the areas does not increase by the coating process and maintain the original temperature of the areas. In other embodiments, for the areas that need to be cooled down, the patterned mask may also be used to etch the coating film to reduce the thickness of specific areas so that the areas result in a reduction in the temperature (less heat provided) during the process. The materials used in the patterned coating film 28 may include silicon carbide, tantalum carbide (TaC), graphite, ceramic, quartz, graphene, diamond-like film, or a combination thereof. According to the embodiments of the present disclosure, by coating a protective film on the surface of the supporting parts 27, the top of the supporting parts 27 is higher than the top of the patterned coating film 28 in the thickness direction of the susceptor 22 so that the patterned coating film 28 does not directly contact with the wafer.

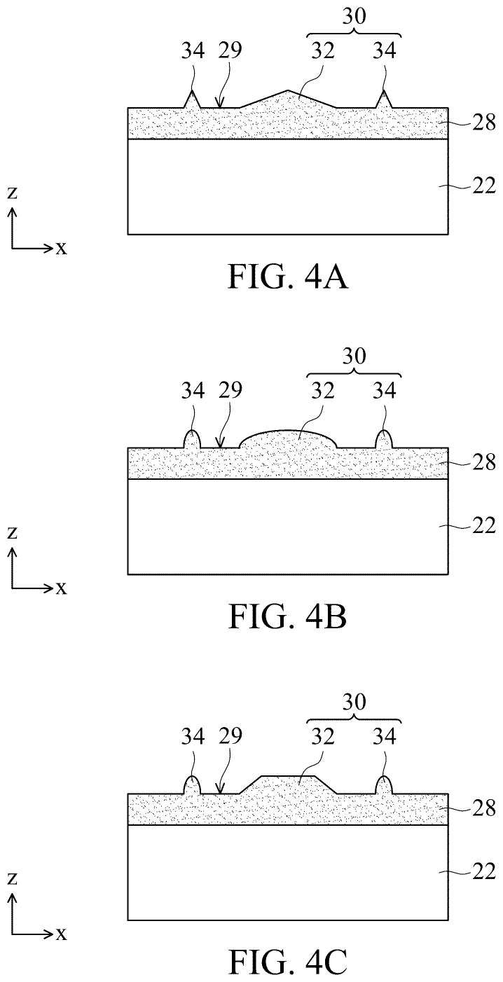

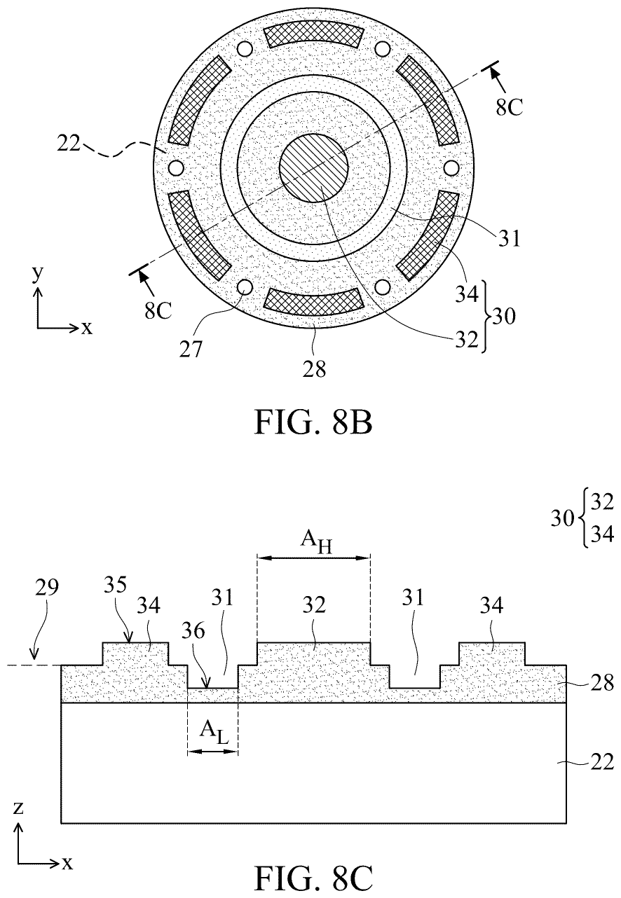

Referring to FIG. 3B, FIG. 3B illustrates a cross-sectional view of the susceptor 22 along line 3B-3B in FIG. 3A. In the embodiments of the present disclosure, the patterned coating film 28 may include a reference surface 29, and a protrusive portion 30 above the reference surface 29, a depressed portion 31 below the reference surface 29 (described in FIG. 8C), or a combination thereof. The patterns of the patterned coating film 28 are symmetrically distributed with respect to the center of the susceptor 22. Referring to FIGS. 3A and 3B, the protrusive portion 30 includes a first protrusive portion 32 and a second protrusive portion 34 surrounding the first protrusive portion 32. The first protrusive portion 32 covers the center of the susceptor 22, and the second protrusive portion 34 is disposed annularly on the susceptor 22 in FIG. 3A; i.e., the second protrusive portion 34 is a continuous annular structure. In these embodiments, the first protrusive portion 32 and the second protrusive portion 34 each have a top surface 35 at the same level, but the present disclosure is not limited thereto. In other embodiments, the cross-sectional shape of the protrusive portion 30 may be a rectangle, a trapezoid, an arc, a triangle, or a combination thereof, as illustrated in FIGS. 4A, 4B and 4C.

Still referring to FIGS. 3A and 3B, in some embodiments, the diameter D1 of the susceptor 22 ranges from about 25 mm to about 250 mm, e.g., 150 mm. In some embodiments, the first protrusive portion 32 or/and the second protrusive portion 34 of the protrusive portion 30 has a thickness Tl of the patterned coating film 28 (i.e., the thickness of the protrusive portion relative to the reference surface 29) in the range of about 1 μm to about 100 μm. According to embodiments of the present disclosure, the ratio of the thickness T1 of the patterned coating film 28 to the diameter DI of the susceptor 22 ranges from about 0.0006% to about 0.7%. In some embodiments, the diameter D2 of the first protrusive portion 32 located at the center of the susceptor 22 ranges from about 1 mm to about 50 mm. According to embodiments of the present disclosure, the ratio of the diameter D2 of the first protrusive portion 32 located at the center of the susceptor 22 to the diameter D1 of the susceptor 22 ranges from greater than 0 to less than ⅓.

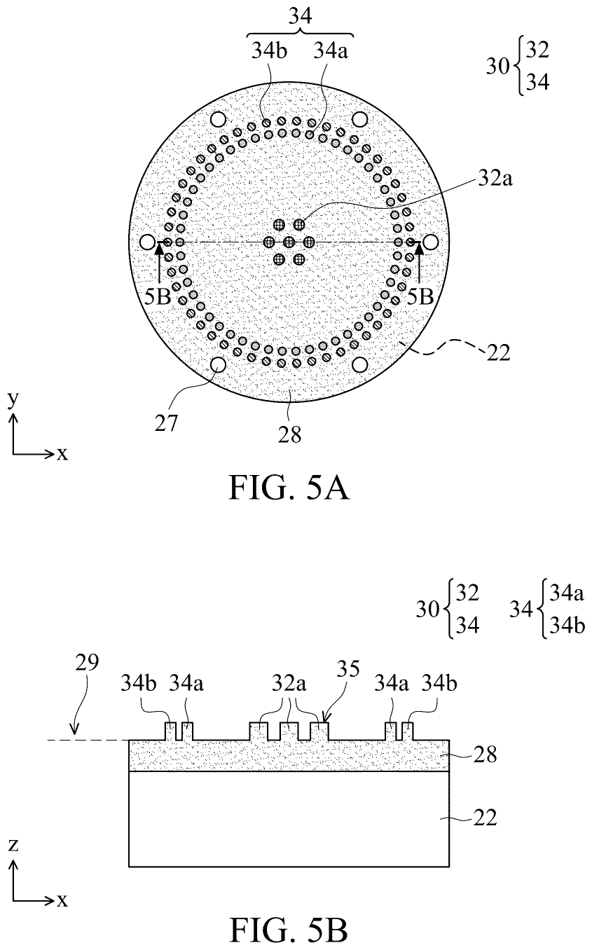

Referring to FIG. 5A, FIG. 5A is a modification of FIG. 3A, in this modified embodiment, the first protrusive portion 32 and the second protrusive portion 34 are intermittently distributed on the susceptor 22. Specifically, the first protrusive portion 32 includes a plurality of intermittent first patterns 32a, which symmetrically distributed with respect to the center of the susceptor 22. The second protrusive portion 34 includes a plurality of intermittent second patterns 34a which are closer to the center of the susceptor 22 and a plurality of intermittent third patterns 34b which are closer to the edge of the susceptor 22, both of which are arranged in a annular manner around the center of the susceptor 22 and are symmetrically distributed with respect to the center of the susceptor 22. In FIG. 5A, the first pattern 32a, the second pattern 34a, and the third pattern 34b are circles. In other embodiments, these patterns may be rectangles, prisms, trapezoids, triangles, or a combination thereof. FIG. 5B illustrates a cross-sectional view of the susceptor 22 along line 5B-5B in FIG. 5A. In this modified embodiment, the first pattern 32a of the first protrusive portion 32 has the top surface 35 level with the second pattern 34a of the second protrusive portion 34 and the third pattern 34b of the second protrusive portion 34, but the present disclosure is not limited thereto.

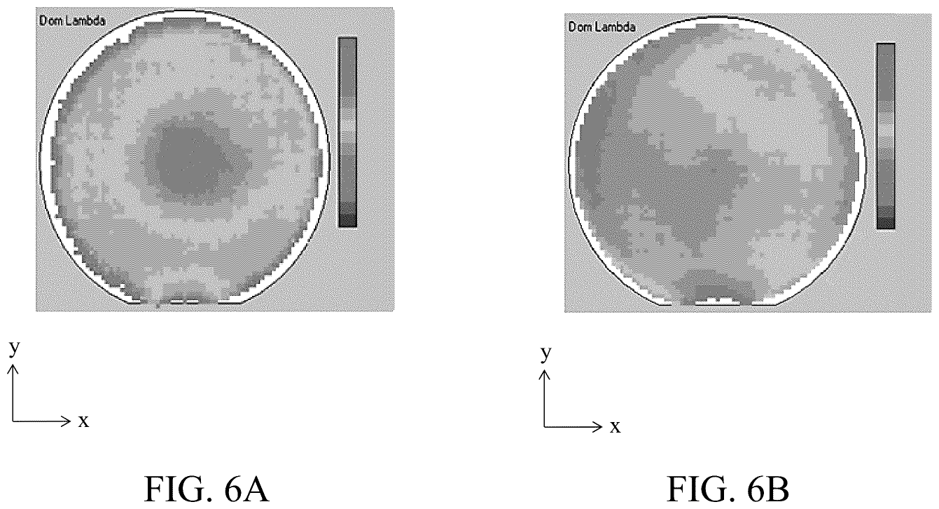

By forming a patterned coating film 28 on the susceptor 22, the temperature field distribution of the carrier structure 18 may be effectively improved. FIG. 6A illustrates a light-emitting wavelength distribution profile of a micro LED manufactured by using the susceptor 22 without the patterned coating film 28. In FIG. 6A, the light-emitting wavelength has a gradient shape radiated from the center to the outside, so the wavelength distribution profile in each area is nonuniform. FIG. 6B illustrates a light-emitting wavelength distribution profile of a micro LED manufactured by using the susceptor 22 with the patterned coating film 28. As shown in FIG. 6B, the area distribution of each gradient (wavelength) of the epitaxial layer on the susceptor 22 is widened, indicating that the gradient (wavelength) of the wafer tends to change more slowly, and effectively improving the uniformity of the light-emitting wavelength of the micro LED.

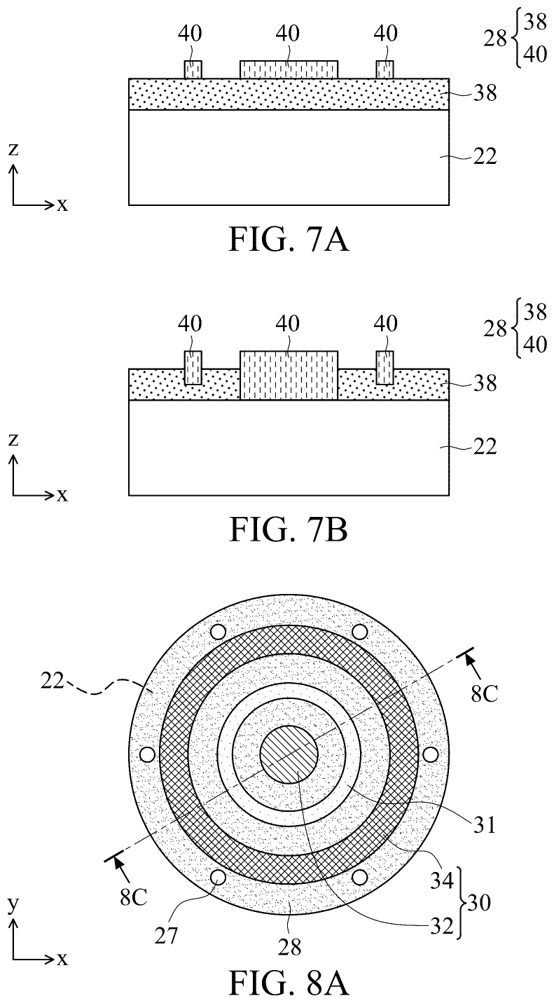

FIG. 7A illustrates a modification of FIG. 3B, in this modified embodiment, two or more different materials are used to form stacked patterned coating films 28. As shown in FIG. 7A, the stacked patterned coating films 28 include an unpatterned first coating film 38 and a second coating film 40. The first coating film 38 is located on the susceptor 22, the second coating film 40 is located on the first coating film 38, and the material of the second coating film 40 is different from the first coating film 38. The second coating film 40 is patterned and distributed on the susceptor 22. Further, as shown in FIG. 7B, the second coating film 40 may also be stacked only partially on the first coating film 38. In other embodiments, other portions of the second coating film 40 may not be located on the first coating film 38, such as the central area of the susceptor 22 in FIG. 7B, where the first coating film 38 may also be completely penetrated, and the penetrated area is replaced by the second coating film 40. The modification of these arrangements is to make the different thermal mass of each part with materials which are different in heat transfer coefficients, so as to control the heat transfer rate in each area. To sum up, in FIG. 7B, if the second coating film 40 is a material with higher heat transfer rate/smaller specific heat, the thermal mass in the area is smaller and the heat dissipation is faster. It is feasible that heating up or cooling down specific areas with materials with different heat transfer coefficients.

In the embodiments of the present disclosure, the patterned coating film 28 may have different thicknesses. According to some embodiments, FIGS. 8A and 8B illustrate a top view of a susceptor 22 with three different thicknesses of a patterned coating film 28. FIG. 8C illustrates a cross-sectional view of the susceptor 22 along line 8C-8C in FIGS. 8A and 8B. Referring to FIG. 8A, in some embodiments, the patterned coating film 28 includes a protrusive portion 30 and a depressed portion 31, wherein the protrusive portion 30 includes a first protrusive portion 32 and a second protrusive portion 34 surrounding the first protrusive portion 32, the depressed portion 31 is located between the first protrusive portion 32 and the second protrusive portion 34 and surrounds the first protrusive portion 32, the second protrusive portion 34 and the depressed portion 31 are both in a annular shape. In other embodiments, as shown in FIG. 8B, the second protrusive portion 34 is an intermittently annular pattern with the intermitter located near the supporting parts 27. Referring to FIG. 8C, in the cross-sectional view, the first protrusive portion 32 and the second protrusive portion 34 each have a top surface 35 at the same level, wherein the top surface 35 is higher than the reference surface 29, while the depressed portion 31 has a bottom surface 36 and the bottom surface 36 is lower than the reference surface 29. Thus, the embodiments of the present disclosure form the patterned coating film 28 with different thicknesses to increase the thickness of the area AH (such as the protrusive portion 30 shown in FIGS. 8A and 8B) where the temperature needs to be increased, and to decrease the thickness of the area AL (such as the depressed portion 31 shown in FIGS. 8A and 8B) where the temperature needs to be decreased. It should be understood that although a single material is used to form the patterned coating film 28 in FIGS. 8A, 8B and 8C, the patterned coating film 28 might also be formed of using various different materials with reference to the embodiments in FIG. 7A.

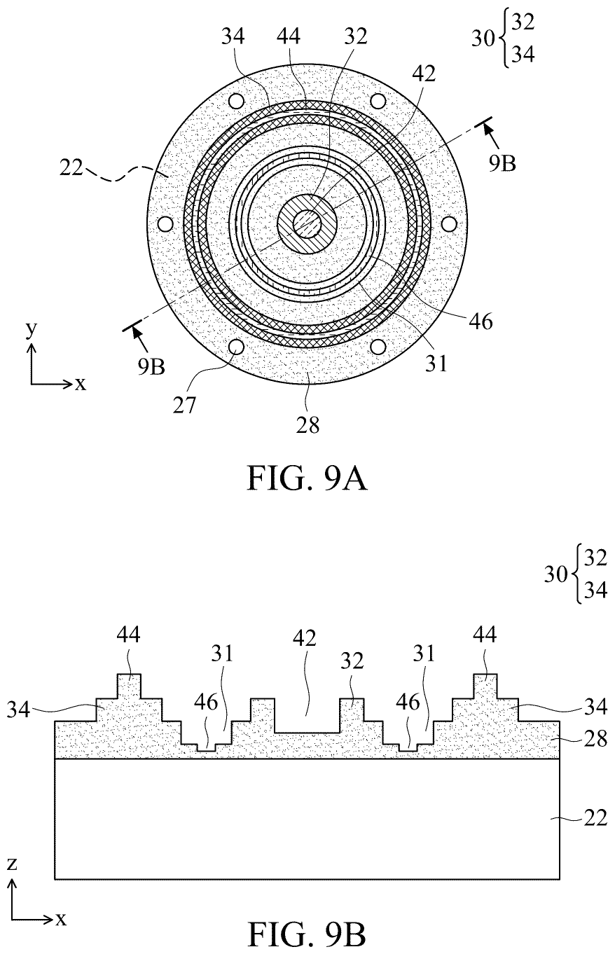

In the embodiments of the present disclosure, different protrusive portions may also have different heights, and each protrusive portion/depressed portion may have two or more thickness variations and may be in a step shape, as illustrated in FIGS. 9A and 9B. According to some embodiments, FIG. 9A illustrates a top view of a susceptor 22 with a plurality of different thicknesses of a patterned coating film 28. FIG. 9B illustrates a cross-sectional view of the susceptor 22 along line 9B-9B in FIG. 9A. Referring to FIG. 9A, along with FIG. 9B, the protrusive portion 30 includes a first protrusive portion 32 and a second protrusive portion 34 surrounding the first protrusive portion 32; the depressed portion 31 is located between the first protrusive portion 32 and the second protrusive portion 34 as well as surrounding the first protrusive portion 32, and the second protrusive portion 34 and the depressed portion 31 both are an intermittently annular pattern. In these embodiments, the center of the first protrusive portion 32 further includes an inner depressed portion 42, the second protrusive portion 34 includes a multi-step protrusive portion 44, and the depressed portion 31 includes a multi-step depressed portion 46. In these embodiments, the thicknesses of the protrusive portion 30 and the depressed portion 31 vary in a step-shape manner, and the temperature field distribution of the carrier structure 18 is adjusted as required with the various thickness of the patterned coating film 28.

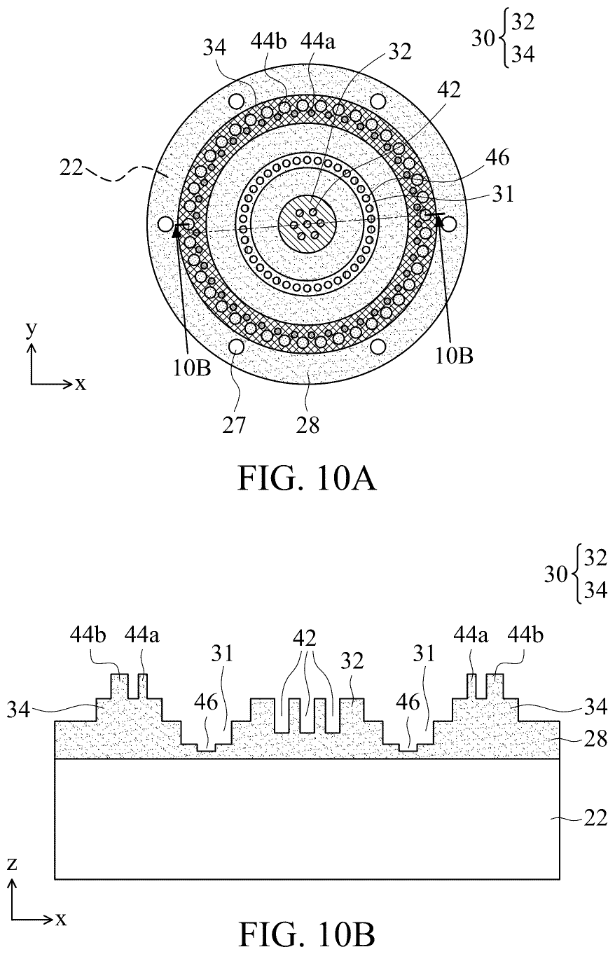

FIG. 10A illustrates another modification of the present disclosure, which is a top view of a susceptor 22 with a plurality of different thicknesses and intermittent patterns of a patterned coating film 28. FIG. 10B illustrates a cross-sectional view of the susceptor 22 along line 10B-10B in FIG. 10A. Referring to FIG. 10A, in this modified embodiment, the inner depressed portion 42 of the first protrusive portion 32, the multi-step protrusive portion 44 of the second protrusive portion 34 (including the protrusive portion patterns 44a and 44b), and the multi-step depressed portion 46 of the depressed portion 31 are arranged in an intermittently annular pattern in the top view. The pattern of the inner depressed portion 42 of the first protrusive portion 32 is symmetrically distributed with respect to the center of the susceptor 22. The protrusive portion patterns 44a and 44b of the multi-step protrusive portion 44 of the second protrusive portion 34 are closer to the center and edge of the susceptor 22, respectively, and are staggered and arranged in an annular shape around the center of the susceptor 22, and are symmetrically distributed with respect to the center of the susceptor 22. The patterns of the multi-step depressed portion 46 of the depressed portion 31 are symmetrically distributed with respect to the center of the susceptor 22. The patterns described above may include a rectangle, a prism, a trapezoid, a circle, a triangle, or a combination thereof. Referring to FIG. 10B, compared to FIG. 9B, the protrusive portion 30 and the depressed portion 31 both have a multi-step thickness variation area, and the protrusive portion and depressed portion patterns described in FIG. 10B are in a cylinder shape (a rectangle in the cross-sectional view). With the intermittently annular patterns to form a patterned coating film 28, the temperature field distribution may be more finely tuned as required.

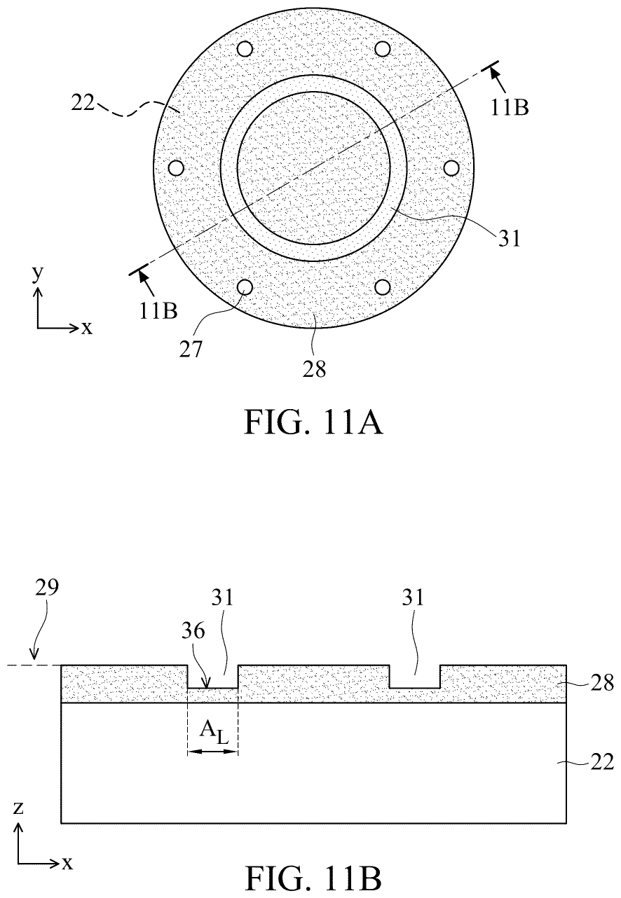

According to some embodiments, the patterned coating film 28 may only form the depressed portion 31, without the protrusive portion 30. FIG. 11A illustrates a top view of a susceptor 22 with a patterned coating film 28 only having a depressed portion 31. FIG. 11B illustrates a cross-sectional view of the susceptor 22 along line 11B-11B in FIG. 11A. In these embodiments, the susceptor 22 only has the area AL where the temperature needs to be decreased, so the patterned coating film 28 only has a depressed portion and no protrusive portion.

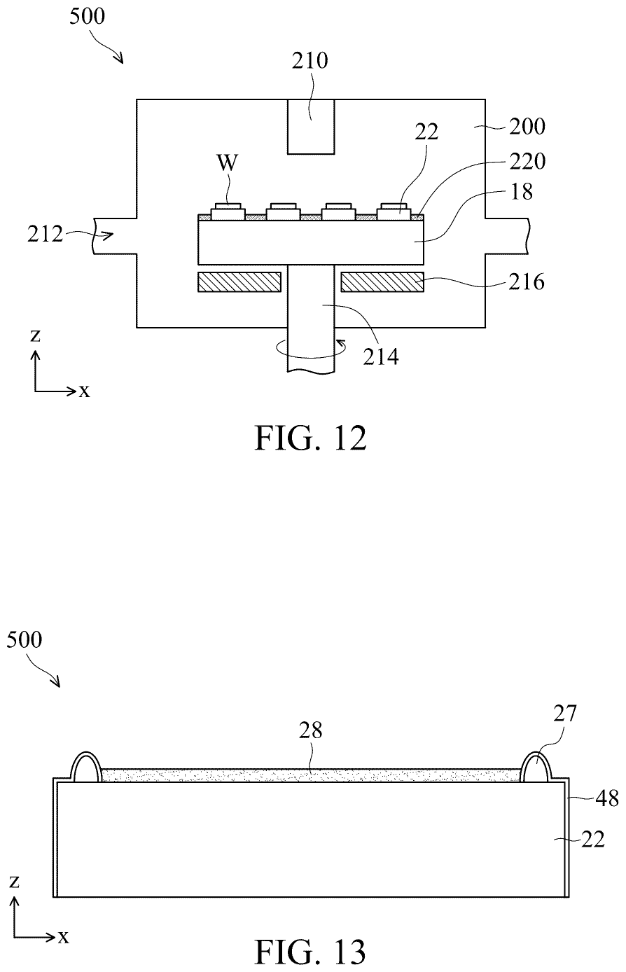

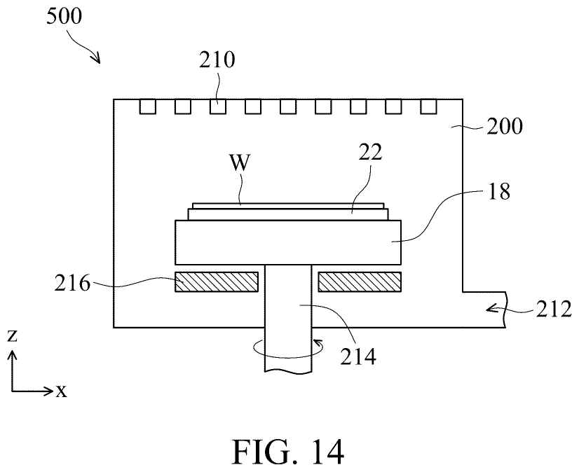

FIGS. 12 and 14 illustrate a cross-sectional view of a MOCVD device 500 according to the embodiments of the present disclosure. Referring to FIG. 12, the MOCVD device 500 includes a chamber 200 with an injecting port 210 and a venting port 212. The injecting port 210 is used to inject the process gas into the chamber 200, and the venting port 212 is used to extract the remaining process gas and the reaction residue from the chamber 200. The chamber 200 has a support member 214 and a heater 216. The support member 214 is a rotatable member. The support member 214 supports the carrier structure 18, and the heater 216 is disposed below the carrier structure 18 to heat the carrier structure 18. In some embodiments, the carrier structure 18 includes a carrier body 20 and a plurality of susceptor 22. The susceptor 22 are separated from each other by spacers 220, and the susceptor 22 are symmetrically distributed with respect to the center of the carrier body 20. Semiconductor wafers W are carried on the susceptor 22. The support member 214 rotates the carrier structure 18 and the semiconductor wafer W above the carrier structure 18. Referring to FIG. 13, a passivation layer 48 may also be formed on the peripheral surface of the susceptor 22 to protect the susceptor 22 from corrosion by the process gas during the MOCVD process, and the passivation layer 48 may be made of a different material than the patterned coating film 28, such as silicon dioxide or another suitable material, depending on the properties of the process gas.

It should be understood that in other embodiments, the carrier body 20 may have only one susceptor 22, as illustrated in FIG. 14. Referring to FIG. 14, in other embodiments, the carrier structure 18 includes a carrier body 20 and one susceptor 22. The carrier structure 18 rotates on its axis only by the support member 214 below. In addition, the chamber 200 may also have a plurality of injecting ports 210, as illustrated in FIG. 14.

Thus, the various embodiments described herein offer several advantages over the existing art. It will be understood that not all advantages have been necessarily discussed herein, no particular advantage is required for all embodiments, and other embodiments may offer different advantages. Compared to the conventional techniques that used mechanical processing to vary the thickness of the susceptor, in some embodiments of the present disclosure, by forming a patterned coating film on the susceptor, it is possible to fine-tune the temperature difference on the surface of the susceptor more precisely during the manufacturing process, avoiding the problem of nonuniform reaction temperature during the epitaxial process, and enabling the subsequent manufactured micro LED chips to have a uniform light-emitting wavelength. In other embodiments, the temperature field distribution on the surface of the susceptor may also be adjusted according to the desired temperature modulation of the target wafer (e.g., temperature modulation corresponding to the wavelength design of the micro LED chips) or a specific mode of the temperature field distribution may be generated, so that the resulting micro LED chips may have a specific wavelength distribution.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor wafer carrier structure, comprising:
a carrier body having a surface;
a protective film covering the surface;
a susceptor disposed on the carrier body and having an upper surface, wherein the upper surface is a planar surface; and
a patterned coating film formed on the upper surface of the susceptor and configured to directly face a semiconductor wafer,
wherein a material of the patterned coating film is different from a material of the susceptor,
wherein the patterned coating film has two or more different thicknesses and is with a pattern, so that the semiconductor wafer is at least locally separated from the patterned coating film due to the pattern,
wherein the patterned coating film is continuously and entirely distributed on the upper surface of the susceptor toward the semiconductor wafer, and the upper surface of the susceptor is separated from the semiconductor wafer by the patterned coating film.

2. The semiconductor wafer carrier structure as claimed in claim 1, wherein the pattern of the patterned coating film is symmetrically distributed with respect to a center of the susceptor.

3. The semiconductor wafer carrier structure as claimed in claim 1, wherein the patterned coating film is defined with a reference surface, and the patterned coating film further comprises a protrusive portion with a top surface above the reference surface, a depressed portion with a top surface below the reference surface, or a combination thereof.

4. The semiconductor wafer carrier structure as claimed in claim 3, wherein the protrusive portion is configured to increase a temperature in one area of the upper surface, and the depressed portion is configured to decrease a temperature in another area of the upper surface.

5. The semiconductor wafer carrier structure as claimed in claim 3, wherein the protrusive portion comprises a first protrusive portion and a second protrusive portion surrounding the first protrusive portion.

6. The semiconductor wafer carrier structure as claimed in claim 5, wherein the first protrusive portion covers a center of the susceptor.

7. The semiconductor wafer carrier structure as claimed in claim 6, wherein the second protrusive portion is disposed annularly on the susceptor.

8. The semiconductor wafer carrier structure as claimed in claim 5, wherein the depressed portion is located between the first protrusive portion and the second protrusive portion and surrounds the first protrusive portion, and the second protrusive portion and the depressed portion are both in an annular shape.

9. The semiconductor wafer carrier structure as claimed in claim 1, wherein the patterned coating film forms only a depressed portion without protruding.

10. The semiconductor wafer carrier structure as claimed in claim 1, wherein the patterned coating film is formed of a single material and with various thicknesses.

11. The semiconductor wafer carrier structure as claimed in claim 10, wherein a thickness of the patterned coating film varies in a step-shape manner.

12. The semiconductor wafer carrier structure as claimed in claim 1, wherein the susceptor has a plurality of supporting parts protruding from the upper surface and located at an edge of the susceptor, and wherein a top of each of the supporting parts is higher than a top of the patterned coating film in a thickness direction of the susceptor.

13. The semiconductor wafer carrier structure as claimed in claim 1, wherein a ratio of a diameter of the patterned coating film at a center of the susceptor to a diameter of the susceptor ranges from greater than 0 to less than ⅓.

14. The semiconductor wafer carrier structure as claimed in claim 1, wherein a passivation layer is formed on a peripheral surface of the susceptor and exposed the upper surface of the susceptor where the patterned coating film is formed, and a material of the passivation layer is different from a material of the patterned coating film.

15. The semiconductor wafer carrier structure as claimed in claim 1, wherein the pattern is corresponding to a patterned mask used to form the patterned coating film on the susceptor.

16. The semiconductor wafer carrier structure as claimed in claim 1, wherein the patterned coating film is formed from various materials with different heat transfer coefficients.

17. A metal-organic chemical vapor deposition device, comprising:
a chamber;
the semiconductor wafer carrier structure as claimed in claim 1 placed in the chamber;
a support member for supporting the semiconductor wafer carrier structure; and
a heater disposed below the semiconductor wafer carrier structure for heating the semiconductor wafer carrier structure.

18. A semiconductor wafer carrier structure, comprising:
a carrier body having a surface;
a protective film covering the surface;
a susceptor disposed on the carrier body and having an upper surface, wherein the upper surface is a planar surface and is divided into a peripheral surface and a partial surface, the susceptor is provided with a plurality of supporting parts protruding from the peripheral surface and individually distributed around a perimeter of the susceptor, and the supporting parts are configured to support a semiconductor wafer;
a passivation layer formed on the peripheral surface of the susceptor and the supporting parts and exposing the partial surface of the susceptor; and
a patterned coating film formed on the partial surface of the susceptor and configured to directly face the semiconductor wafer, wherein a material of the patterned coating film is different from a material of the susceptor, the patterned coating film has two or more different thicknesses to form a pattern between the supporting parts, and a top of the supporting parts is higher than a top of the patterned coating film in a thickness direction of the susceptor, so that the semiconductor wafer is entirely separated from the pattern of the patterned coating film,
wherein the passivation layer and the patterned coating film are continuously and entirely distributed on the upper surface of the susceptor toward the semiconductor wafer, and the upper surface of the susceptor is separated from the semiconductor wafer by the passivation layer and the patterned coating film.
